(19) United States
(12) Patent Application Publication
(10) Pub. No.: US 2002/0102745 A1
(43) Pub. Date: Aug. 1, 2002

(54) Process for modifying chip assembly substrates

(75) Inventors: Syamal Kumar Lahiri, Kent Vale (SG); Harvey Monroe Phillips, Oceanside, CA (US)

Correspondence Address: LADAS & PERRY, 5670 Wilshire Boulevard, Suite 2100, Los Angeles, CA, 90036-5679, US

(73) Assignee: Institute of Materials Research & Engineering

(21) Appl. No.: 09/921,346

(22) Filed: Aug. 2, 2001

(30) Foreign Application Priority Data
Aug. 3, 2000 (SG) 200004356-2

(51) Int. Cl. H01L 21/00; H01L 21/44

(52) U.S. Cl. 438/4; 438/678; 438/687

(57) ABSTRACT

A method of modifying a chip assembly substrate comprising the steps of:

treating a selected area of the substrate to provide the selected area with a predetermined charge;

texturing the selected area of the substrate to affect the texture of the substrate surface;

depositing an electro-less plating catalyst, having an opposite charge to that of the predetermined charge, to at least the selected area of the substrate such that the catalyst remains affixed to the selected area of the substrate only; and

modifying the chip assembly substrate by electro-less plating the chip assembly substrate, only those areas to which the catalyst remains affixed being electro-less plated.

THIS INVENTION relates to a process of modifying chip assembly substrates.

More particularly, the present invention relates to a method of modifying or repairing chip assembly substrates without requiring lithography or the removal of any previously mounted components if already present.

Once a chip assembly substrate has been manufactured with any surface mount assemblies attached thereto, repair or engineering changes to the circuitry which involves the addition of new traces, typically copper, becomes difficult. Removal of an unwanted circuit part can be readily accomplished by cutting a trace with a laser—a common industrial practice. Adding circuitry, however, using conventional techniques would require the entire substrate to be plated and then any unwanted traces removed through a photolithographic and etching process. The uneven surface profile of chip assembly substrates makes any high-resolution photolithographic process impossible. The adhesion and reliability of any freshly plated copper traces would also be questionable because the normal grinding and surface etch procedures utilised to increase adhesion of the copper traces to the polymer substrate would not be possible. Lack of adhesion of the copper traces to the polymer substrate presents a serious problem. A process, therefore, which could selectively define a circuit pattern and simultaneously selectively prepare the surface for improved trace adhesion would significantly improve the potential for modifying or repairing chip assembly substrates. It should be noted that polymer coated substrates also suffer from the same disadvantage of lack of trace adhesion.

Increasingly, high density substrates are being used and thus the need to make engineering changes, modifications or repairs involving connections on and/or between the outer circuit layer and the first inner layer will become essential.

As substrates become more expensive and more complex, the ability to produce new connections on and/or between the outer circuit layer and the first inner layer and within buried layers, would also increase the flexibility and usefulness of a process able to modify, carry out engineering changes or repair chip assembly substrates.

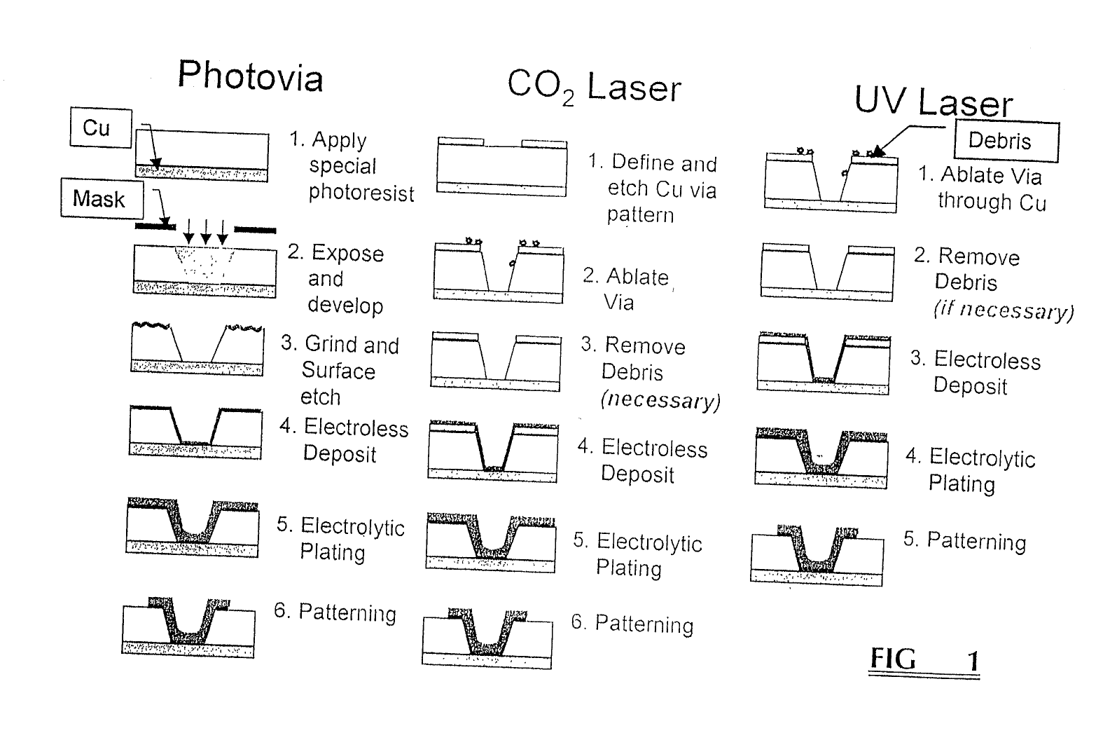

While current methods are suitable for removing circuitry and for micro via formation, these methods have not been used for adding circuitry, or for the metallisation of micro vias. FIG. 1 of the accompanying drawings illustrates three conventional processes for forming micro vias: 1) a photo-defined process utilising a special photo-imageable dielectric which is exposed and developed to produce the vias, a grinding and surface etch step being used to improve adhesion of the plated copper traces; 2) a carbon dioxide laser process which creates a significant amount of debris during the ablation step which must be removed by plasma or some other type of de-smearing process, without de-smearing, adhesion of any plated metal is poor; and 3) a UV laser process in which no pre-etching is required which is advantageous but, when only a dielectric is used, some process steps must be added to prepare the polymer surface of the substrate to enhance adhesion of the plated copper and, as with the photo defined micro via method, this process is incompatible with chip assembly substrates.

All these processes require a photolithographic process for final patterning because the plating step is not area specific or selective. Once any surface mount components are attached to the assembly, it therefore becomes difficult, if not impossible, to make any changes, modifications or repairs. A photolithographic process would also require the production of a new mask for the proposed changes so that modifications or repairs would be expensive and time-consuming especially when only a single or small number of chip assembly substrates are to be modified or repaired.

A method of metallising (or adding traces) to a polymer film is known from Applied Surface Science 69 (1993) 1-6, “Excimer laser polymer ablation: formation of positively charged surfaces and its application into the metallization of polymer films”, Hiroyuki Niino and Akira Yabe. This provides a method of sensitising a predetermined area of a polymer film by applying a laser radiation source thereto:. The sensitisation changes the charge of the predetermined area of the polymer film from a neutral charge to a positive charge. Once specific areas of the polymer film have been charged, then a catalyst is deposited on the charged areas by dipping the polymer film in an aqueous solution containing a negatively charged colloid composed of palladium and a surfactant. The catalyst or a colloid including the catalyst adheres to the selected areas of the substrate surface. The polymer film is then rinsed and immersed in a plating bath of copper. The negatively charged colloid adheres to the polymer film in those specific areas which have been irradiated. The deposition of an electro-less plating layer of copper is limited to those selected areas of the polymer film to which the colloid has adhered. Accordingly, when the selected areas of the polymer film are configured as traces, then electro-less plating of new traces is achieved by this process. However, there is still a problem with adherence of traces to the substrate.

It is an object of the present invention to provide a process for modifying, changing or repairing a chip assembly substrate without the requirement of lithography or necessitating the removal of previously mounted components.

It is a further object of the present invention to seek to provide a process for modifying, changing or repairing a chip assembly substrate which also permits addition of conductive traces with improved adhesion.

It is another object of the present invention to seek to provide a process for modifying, changing or repairing a chip assembly substrate which offers greater flexibility allowing modifications to be made with only software input to a laser system.

A further object of the present invention is to seek to provide a method of modifying chip assembly substrates by the addition and removal, if needed, of interconnections and/or input/output (I/O) pads for the purpose of carrying out repair work or engineering changes or rapid prototyping of chip assembly substrates.

Another object of the present invention is to seek to provide a process for modifying, changing or repairing a buried layer within a chip assembly substrate.

Accordingly, one aspect of the present invention provides a method of modifying a chip assembly substrate comprising the steps of: treating a selected area of the substrate to provide the selected area with a predetermined charge; texturing the selected area of the substrate to affect the texture of the substrate surface; depositing an electro-less plating catalyst, having an opposite charge to that of the predetermined charge, to at least the selected area of the substrate such that the catalyst remains affixed to the selected area of the substrate only; and modifying the chip assembly substrate by electro-less plating the chip assembly substrate, only those areas to which the catalyst remains affixed being electro-less plated.

Preferably, the step of treating and/or texturing the selected area comprises the step of scanning a low fluence laser beam on the selected area.

Conveniently, the fluence of the laser beam is in the range of 0.02 to 0.26 J/cm².

Advantageously, the pulse width of the laser beam on the selected area is in the range of 10 to 50 nanoseconds.

Conveniently, the repetition rate of the laser beam on the selected area is in the range of 5 Hz to 1 kHz.

Preferably, the laser is a UV laser.

Conveniently, the substrate is a polymer substrate or polymer coated substrate.

Preferably, the polymer is an aromatic polymer, or contains an aromatic polymer.

Advantageously, the catalyst comprises negatively charged colloids containing palladium.

Preferably, the texturing step to affect the texture of the substrate surface roughens the surface of the substrate in the selected area.

Conveniently, the treating step and the texturing step comprise the same step.

Advantageously, the fluence of the laser beam is increased from a first fluence level to a final fluence level.

Conveniently, the treating step positively charges the selected area of the substrate.

Advantageously, a trench or via is provided in the substrate down to a buried layer within the substrate such that a connection within the substrate can be added or modified.

Preferably, the step of treating the selected area of the substrate comprises the step of treating the trench or via.

Conveniently, one or more selected areas of the substrate are ablated so as to remove unwanted conductive portions on or in the substrate, the ablation using a high incident fluence.

Advantageously, a laser is provided to carry out the treating step, the laser being switchable between a low fluence setting and a high incident fluence setting.

Preferably, a laser is provided to carry out the treating step and the operating parameters of the laser, including the fluence and the selected area scanned by the laser, are controllable by software.

In order that the present invention may be more readily understood, embodiments thereof will now be described, by way of example, with reference to the accompanying drawings, in which:

FIG. 1 illustrates conventional methods for micro via production;

FIG. 2 comprises two SEM micro-graphs illustrating the conductive traces obtainable using a process embodying the present invention;

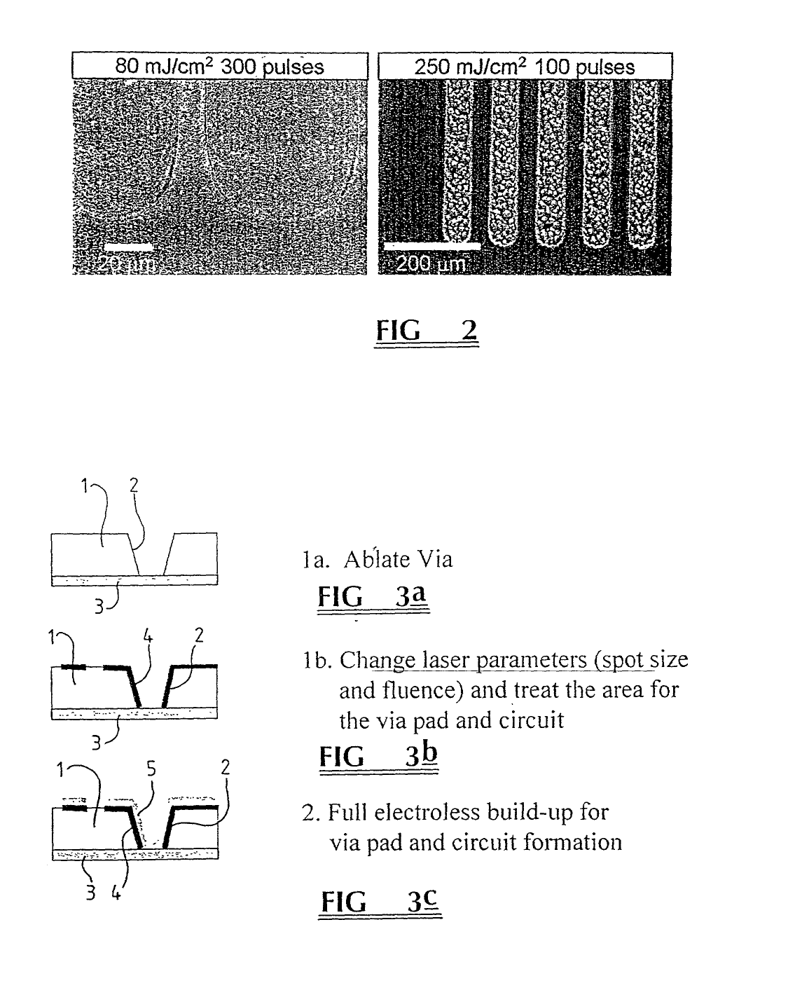

FIGS. 3a to 3c are a series of three cross-sections through a micro via produced in accordance with a process embodying the present invention; and

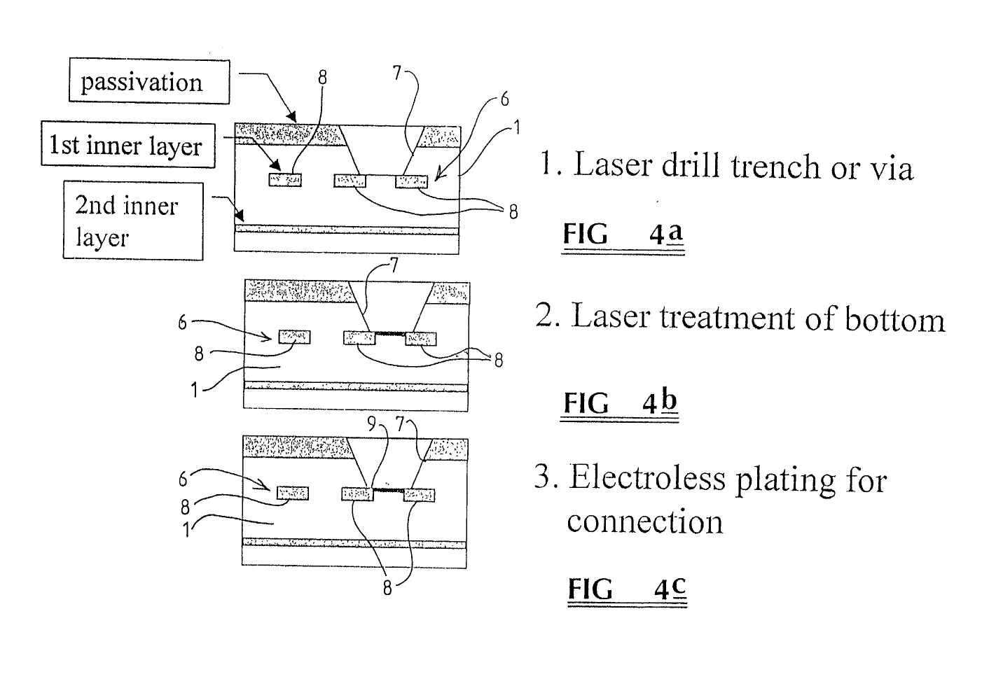

FIGS. 4a to 4c are a series of three cross-sections through a micro via produced in accordance with a process embodying the present invention to make repairs or provide a new connection to a buried layer.

A dramatic change in the surface energy of a polymer substrate occurs when the polymer surface is treated with a low fluence UV laser. When negatively charged colloids containing palladium (Pd) are used as an electro-less plating catalyst, the palladium is selectively deposited only on those areas of the surface which have been laser treated and which are positively charged. As a result, only the laser treated areas are catalysed thus achieving electro-less plating only on selected areas. The aim of the laser treatment hitherto has only been to sensitise the polymer surface of the substrate and to make a selected area positively charged. The aim of the laser treatment embodying the present invention is not only to sensitise the polymer surface of the substrate but also to affect the texture of the substrate surface and preferably roughen the substrate surface. The aim is not to form an electrically conducting layer as would be required for electrolytic deposition techniques. The number of laser pulses required to treat the surface area for use in the process of the present invention is substantially reduced compare to the number of laser pulses which would be required for electrolytic deposition techniques.

As stated above, the substrate surface is treated with a low fluence UV laser. In the context of the present Application, the term “low fluence” refers to parameters of energy per unit area that vary depending on the type of laser, and which may also vary depending on the type of material used. In the case of a KrF (wavelength 248 nm) laser, the critical fluence range is from about 0.02 to 0.26 J/cm². For other mentioned lasers, the critical fluence range is of the same order.

The use of the low fluence UV laser treatment on the substrate surface roughens the surface. This is extremely advantageous because the roughened surface will enhance the adhesion of any subsequently plated metal traces or pads to the substrate surface. However, excessive roughening of the substrate of the substrate may be disadvantageous, as plating may become non-uniform and some areas may not be plated at all. A suitable amount of roughening can be achieved by varying the fluence of the laser and the number of pulses incident on the surface. The preferred level of roughness is root mean square (RMS) roughness of between 0.2 to 0.5 μm. Excessive roughness is greater than an RMS roughness of 1.5 μm.

A preferred method of achieving a desired level of roughness is to employ a multistage “ramp” of the fluence of the laser. The surface is first irradiated with low fluence pulses of the laser beam that are just within the critical fluence range of the laser (for instance 40 mJ/cm²) for a small number of pulses to sensitise the selected areas of the substrate surface. The fluence of the laser beam is then increased in a succession of steps until the final (though still within the critical range) fluence is reached (for instance 0.2J/cm²). It has been found that using this method, a fine scale roughness (<0.5 microns) is achieved over a large area, and good adhesion of the catalyst is obtained.

The profile of the ramp can be varied as desired and could, for example, firstly provide a series of low fluence pulses and then follow on with a series of high fluence pulses to gain not only improvements in surface roughness but also to provide a more highly charged surface which would accept colloids more readily. The increase in fluence may be effected as a constant increase from the first low fluence level to the final higher fluence level.

Initial tests of adhesion of electro-less plated copper traces on a polyimide substrate have been encouraging and show that adhesion was significantly better than copper traces deposited with an electrolytic process.

An example of a process embodying the present invention will now be described with reference to FIGS. 3a to 3c. FIG. 3a illustrates a substrate 1 formed with a micro via 2 which has been ablated using conventional techniques. The micro via 2 provides access from the substrate surface to a conductive layer 3 below the substrate. Preferably, a UV laser removes any unwanted passivation layer and drills the necessary vias in the substrate. Typically, the substrate will comprise an aromatic polymer such as a polyimide or an epoxy. The UV laser is operated at a high incident fluence during this step to increase the speed of the process.

It has been found that ramping the fluence both treats and textures the substrate by creating a high density of shallow dimples in the treated area, the dimples having a depth of within the desired range of less than or equal to 0.5 μm when the fluence levels are maintained within the aforementioned critical fluence range. Simple irradiation at a single high fluence level within the critical range, i.e. with no ramping, can provide a surface roughness which exceeds the desired roughness, whereas ramping the fluence level to the same high fluence level does not cause the roughness to exceed the desired level, i.e. an RMS roughness of ≦1.5 μm.

In the context of the present Application, a high incident fluence means a fluence greater than about 1 J/cm².

The next step in the process is to remove any unwanted conductive portions such as circuit traces, via or contact pads. Again, the UV laser is switched to a high incident fluence to ablate any such circuit traces.

The UV laser is then switched (controlled by software) to a lower fluence setting and the selected areas of the surface of the substrate are treated with the low fluence beam. The treatment step involves scanning the laser with a sufficient number of laser pulses per unit area to ensure that the polymer surface is adequately positively charged and adequately roughened. FIG. 3b shows the selected area 4 of the micro via 2 which has been treated by the low fluence laser.

It should be noted that no handling of the substrate is required between the step of obtaining the micro via 2 (FIG. 3a) and the step of treating the substrate (FIG. 3b).

In the case of via pads, an entire pad area can be processed simultaneously if the spot size of the laser beam can be made sufficiently large. The fluence of the laser beam is maintained within the critical range when the spot size is increased.

After the selected area of the chip assembly substrate has been treated by the low fluence laser, the treated substrate is cleaned with an organic solvent and rinsed in DI water.

The substrate is then dipped for a short time (in the order of 60 secs) in NaOH and subsequently rinsed thoroughly with DI water.

The substrate is then placed in a bath containing negatively charged palladium colloids. The negatively charged palladium colloids attach only to the selected areas of the chip assembly substrate which have been treated by the low fluence laser. Thus, only those treated areas of the surface are catalysed for subsequent electro-less deposition.

The final step in the process is to deposit the new conductive portions, comprising copper traces, using normal electro-less plating solutions and processes. The deposition could be either a full-build electro-less process or a standard electro-less process followed by an electrolytic process. FIG. 3c illustrates the micro via 2 plated with a new copper trace 5. If required or desired, electrolytic plating can be carried out after the step of electro-less deposition.

It should be appreciated that the above process contains no requirement for lithography. Because the electro-less plating is strictly limited to the selected areas of the substrate which have been treated by the low fluence laser, the process is essentially additive in nature and thus the amount of laser processing is minimised. The selection of areas to be changed, modified or repaired can thus be controlled by simple changes to the software parameters input to the laser system.

The laser can be any one of a number of common UV lasers such as 3rd or 4th harmonics of an Nd:YAG laser or any other excimer laser. An assist gas might be used to enhance the effectiveness of the laser processing.

Referring now to FIGS. 4a to 4c, it will be apparent that the above described process is also able to make repairs where new connections to buried layers 6 within a substrate 1 are required. The laser can ablate a trench 7 within the substrate 1 to expose the traces 8 in the buried layers 6 (as shown in Figure 4a) that are to be interconnected. The surface at the bottom of the trench 7 is then treated with the low fluence laser (as shown in FIG. 4b). A new conductive portion 9 is then plated onto the bottom of the trench 7 to connect the traces 8 within the buried layer 6 as shown in FIG. 4c in accordance with the process described in relation to FIGS. 3a, 3b and 3c.

Thus, in accordance with an embodiment of the present invention, changes, modifications or repairs can be made to buried layers of an existing chip assembly substrate without necessitating removal of components already mounted on the substrate surface.

It will be appreciated that as high density substrates become more complex and represent an even greater percentage of the cost of a product, then the incentive to repair defective substrates or to make engineering changes or modifications will increase dramatically. The processes embodying the present invention meet this need.

It will be noted that processes embodying the present invention permit the addition of metal traces with improved adhesion to implement modifications, changes or repairs to an existing chip assembly substrate. Passivation layers present on a substrate would only have to be removed locally by the laser so that the rest of the substrate and any mounted components can remain in place and protected by their passivation layers during subsequent processing steps.

The spatial resolution which can be achieved by processes embodying the present invention show that 50 μm lines and spaces can easily be obtained as shown in FIG. 2. Where larger areas need to be plated, for example via pads, the edge definitions provided using processes embodying the present invention provide good results. Plating two regions separated by less than 20 μm has also been demonstrated. Such resolutions are entirely suitable for most applications in the PCB industry.

The ability to provide electro-less deposition with improved adhesion on only selected areas of a chip assembly substrate allows modifications, changes or repairs to be made without the need for a mask and, if desired, without the need to remove surface mounted assemblies, if desired.

Although the above embodiment uses a negatively charged colloid, it is envisaged that the present invention may be performed using a positively charged colloid. In this instance, a system would be required that produced a negatively charged surface area.

It is envisaged that, as well as finding use in repairing and modifying chip substrates, the present invention would be suitable for rapidly creating prototypes, or for small-volume production, of chip assembly substrates. In this case, all or most of the interconnection lines and I/O pads on the outer polymer layers of the substrate, including buried layers would be delineated by this technique prior to chip assembly operations.

Lasers which are particularly useful for carrying out the present invention are pulsed lasers which are specified by their individual pulse energy and the pulse repetition rate. The average power output of such a pulse laser is simply the individual pulse energy multiplied by the repetition rate. Some examples of pulse lasers are Nd: YAG, Nd: Glass, KrF, ArF, XeCl, XeF, KrCl and F₂ excimer lasers. Since such lasers typically have an unstable laser cavity, the output beam is quite large but the resultant spot size generated thereby is not critical to the invention. As previously stated, the concept of the invention depends on the energy deposited per pulse per unit area, i.e. in the instant energy density per pulse, or fluence. For excimer lasers, the beam is normally quite uniform and the fluence is determined by measuring the incident energy and dividing by the irradiated area.

The process of the present invention has been shown to work with lasers having wavelengths less than 400 manometres although it is envisaged that lasers having greater wavelengths could also be used.

Pulse widths are typically in the region of 10 to 50 nanoseconds. It is envisaged that lasers having sub-picosecond pulse widths would not be suitable for use with the present invention.

Repetition rates in the order of up to 20 kHz have been shown to be useful for carrying out the present invention.

Some of the lasers which are used to perform the invention, e.g. YaG lasers, have a beam with a Gaussian distribution, where approximately 86% of the laser energy is in the area defined by the spot size. In some embodiments of the present invention, optical systems can be used to shape the beam and provide a greater concentration of energy within the spot size. Such beam profiling would change the beam profile from the Gaussian distribution to a stepped or squared distribution.

It should also be appreciated that the invention will work with an imaged beam or a focused beam. Using an imaged beam, the pattern where plating is desired is irradiated for a specified number of pulses. The sample could then be moved on to the next location and the process repeated with the same or a different pattern. The number of pulses for each sample would typically be between 50 to 500 or perhaps as much as 1000. The precise number of pulses is dependent upon the incident fluence, the laser repetition rate, the laser wavelength and the type of substrate being irradiated.

It is also possible to use a focused beam scanned across a sample rather than using an imaged beam. Again, the critical parameters are the fluence and the number of pulses per area. The number of pulses per area is determined by calculating the time it takes the focused beam to traverse one spot size and multiplying this by the pulse repetition rate: i.e. N=R

$$N = R \cdot \frac{w}{s} ,$$

where:

N=number of pulses per area,

R=pulse repetition rate,

w=laser spot size; and

s=scanning speed.

For example, for a repetition rate of 1 kHz, a spot size of 0.1 mm and a scanning speed of 0.5 mm per second, then N=200.

Whilst the precise range for use with the present invention varies somewhat with the laser which is used, it has been established that preferred embodiments of the invention operate when the incident fluence is within a critical range of approximately 0.02 to 0.26 joules per cm². The fluence required can be readily ascertained by a person of ordinary skill in the art, since if the fluence is too low, then the polymer substrate surface will not be changed but if the fluence is too high, then there will be clean ablation of the substrate surface without surface modification.

Repetition rate is not critical to the present invention although very low repetition rates below, for example, 5 Hz do not produce the best results. Typically, repetition rates in the region of 50 or 100 Hz have been used. There does not appear to be an upper limit on the repetition rate which works with the present invention.

The general concept of the present invention can be carried out without lasers but using some other form of radiation to provide a suitable charge to the surface of the polymer so as to achieve the same results as might be achieved with a laser. Ion beams can produce laser induced conductivity in polymer substrates and it is envisaged that electron beams would achieve the same result. Similarly, X-ray radiation is another convenient alternative form of radiation which could be used.

The ability of laser irradiation to change the surface potential of polymer substrate surfaces is known and it has been identified that the change in surface potential is more noted when irradiation takes place in air rather than in a vacuum.

The term chip assembly substrate refers to a substrate which is either adapted to carry or which carries one or more electronic components requiring interconnection by one or more conductive tracks or traces. The chip assembly substrate may be modified in accordance with the method of the present invention with the electronic components in place or removed or before any components are mounted. It should be appreciated that it is preferable to modify the chip assembly substrate in accordance with the present invention with the electronic components in place so as to minimise the number of operations required to effect the modification. However, some electronic components are particularly sensitive to environmental change and it is beneficial for these to be removed prior to effecting the modification to prevent damage to such sensitive components. Additionally, some modifications may be more easily effected without one or all of the components on the substrate, or indeed before any components are mounted on the substrate. The chip assembly substrate may include a printed circuit board.

Whilst the above description refers to copper traces or tracks, it should be appreciated that nickel or mixtures of copper and nickel can also be used as the material for the conductive traces or tracks.

Polymers for use in the polymer substrate or in the polymer of a polymer coated substrate are polyimide, epoxy and polycarbonate although the method of the invention is not limited to these examples.

In the present specification “comprise” means “includes or consists of” and “comprising” means “including or consisting of”.

The features disclosed in the foregoing description, or the following claims, or the accompanying drawings, expressed in their specific forms or in terms of a means for performing the disclosed function, or a method or process for attaining the disclosed result, as appropriate, may, separately, or in any combination of such features, be utilised for realising the invention in diverse forms thereof.

1. A method of modifying a chip assembly substrate comprising the steps of:
treating a selected area of the substrate to provide the selected area with a predetermined charge;
texturing the selected area of the substrate to affect the texture of the substrate surface;
depositing an electro-less plating catalyst, having an opposite charge to that of the predetermined charge, to at least the selected area of the substrate such that the catalyst remains affixed to the selected area of the substrate only; and
modifying the chip assembly substrate by electro-less plating the chip assembly substrate, only those areas to which the catalyst remains affixed being electro-less plated.

2. A method according to claim 1, wherein the step of treating and/or texturing the selected area comprises the step of irradiating the selected area with a pulsed laser beam.

3. A method according to claim 2, wherein the fluence of the laser beam is in the range of 0.02 to 0.26 J/cm².

4. A method according to claim 2, wherein the pulse width of the laser beam on the selected area is in the range of 10 to 50 ns.

5. A method according to claim 2 or 4, wherein the repetition rate of the laser beam on the selected area is in the range of 5 Hz to 1 kHz.

6. A method according to any one of claims 2 to 5, wherein the laser is a UV laser.

7. A method according to any preceding claim, wherein the substrate is a polymer substrate.

8. A method according to any one of claims 1 to 6, wherein the substrate is a polymer coated substrate.

9. A method according to claim 7 or 8, wherein the polymer is an aromatic polymer, or contains an aromatic polymer.

10. A method according to any preceding claim, wherein the catalyst comprises negatively charged colloids containing palladium.

11. A method according to any preceding claim, wherein the texturing step to affect the texture of the substrate surface roughens the surface of the substrate in the selected area.

12. A method according to any preceding claim, wherein the texturing produces a surface RMS roughness of less than 1.5 μm.

13. A method according to any preceding claim, wherein the texturing produces a surface RMS roughness of between 0.2 to 0.5 μm.

14. A method according to any preceding claim, wherein the treating step positively charges the selected area of the substrate.

15. A method according to any preceding claim, wherein the treating step and the texturing step comprise the same step.

16. A method according to any one of claims 1 to 14, wherein the treating step is carried out with a laser beam at a first fluence level and the texturing step is carried out with a laser beam at a second fluence level, the second fluence level being higher than the first fluence level.

17. A method according to any one of claims 2 to 14, wherein the fluence of the laser beam is increased from a first fluence level to a final fluence level to effect treatment and texturing of the substrate.

18. A method according to claim 17, wherein the fluence is increased in a plurality of discrete steps.

19. A method according to any preceding claim, wherein the substrate contains multi-layer metallisations.

20. A method according to claim 19, further comprising the step of forming a trench or via down to a buried layer within the substrate.

21. A method according to claim 20, wherein the step of treating and/or texturing the selected area of the substrate comprises the step of treating and/or texturing the trench or via.

22. A method according to any preceding claim further comprising the step of adding or modifying a connection on or within the substrate.

23. A method according to any preceding claim, wherein one or more selected areas of the substrate are ablated so as to remove unwanted conductive portions on or in the substrate.

24. A method according to any preceding claim, wherein a laser is provided to carry out the treating and/or texturing step, the laser being switchable between a low fluence setting and a high incident fluence setting.

25. A method according to any preceding claim, wherein a laser is provided to carry out the treating and/or texturing step, the operating parameters of the laser, including the fluence and the selected area scanned by the laser, being controllable by software.

26. A method substantially as hereinbefore described with reference to and as shown in FIGS. 3 and 4.
